(19) United States
(12) Patent Application Publication
(10) Pub. No.: US 2024/0222522 A1
(43) Pub. Date: Jul. 4, 2024

(54) DISPLAY PANEL

(71) Applicant: Guangzhou China Star Optoelectronics Semiconductor Display Technology Co., LTd., Guangzhou (CN)

(72) Inventor: Shuaiyi WANG, Guangzhou (CN)

(73) Assignee: Guangzhou China Star Optoelectronics Semiconductor Display Technology Co., LTd., Guangzhou (CN)

(21) Appl. No.: 18/192,653

(22) Filed: Mar. 30, 2023

(30) Foreign Application Priority Data
Dec. 28, 2022 (CN) 202211716307.2

(51) Int. Cl. H01L 29/786; H01L 29/417

(52) U.S. Cl. CPC H01L 29/78696; H01L 29/41733

(57) ABSTRACT

The present application provides a display panel, the display panel includes an electrostatic protection circuit. The electrostatic protection circuit includes at least one thin film transistor. The thin film transistor includes an active layer. The active layer includes a channel portion. Disposing at least one auxiliary electrode on the channel portion and making the auxiliary electrode contact the channel portion can use the additional auxiliary electrode to increase plasma to affect uniformity of the channel portion such that a leakage current of the thin film transistor is reduced to improve display quality of the display panel.

### FIELD OF INVENTION

The present application relates to a field of display technologies, especially to a display panel.

### BACKGROUND OF INVENTION

In production of a display panel, static electricity is inevitably generated in test and transport processes. An instantaneous high voltage of kilovolt generated due to friction or contact would strike through the display panel and result in component failure inside the display panel.

In related technologies, an electrostatic protection circuit is disposed in a display panel usually to release a high level due to accumulation of static electricity and prevent static electricity from damaging components in the display panel. However, when the display panel works normally, a thin film transistor in the electrostatic protection circuit has a situation of a leakage current, and such situation would cause the display panel unable to normally display grayscale and brightness, which influences display quality of the display panel.

Therefore, it is necessary to provide a display panel to mitigate such defect.

### SUMMARY OF INVENTION

An embodiment of the present application provides a display panel that can reduce a leakage current of a thin film transistor in an electrostatic protection circuit to improve display quality of the display panel.

The embodiment of the present application provides a display panel comprising an electrostatic protection circuit, wherein the electrostatic protection circuit comprises a thin film transistor that comprises an active layer comprising: a channel portion; and at least one auxiliary electrode contacting the channel portion directly.

According to an embodiment of the present application, at least one auxiliary electrode is plural, the auxiliary electrodes are disposed on the channel portion, and the auxiliary electrodes are distributed at intervals along a channel length direction.

According to an embodiment of the present application, the channel portion is at least partially bending.

According to an embodiment of the present application, the channel portion comprises a plurality of bending sections, and bending directions of adjacent two of the bending sections are different.

According to an embodiment of the present application, each of the at least one auxiliary electrode is disposed on each of the bending sections.

According to an embodiment of the present application, the channel portion comprises at least two sub-channel portions, and the sub-channel portions are disposed at intervals along a channel width direction.

According to an embodiment of the present application, adjacent two of the sub-channel portions are parallel to each other or disposed symmetrically.

According to an embodiment of the present application, the thin film transistor further comprises a source electrode and a drain electrode, and the auxiliary electrode, the source electrode, and the drain electrode are disposed in a same layer.

According to an embodiment of the present application, the thin film transistor comprises a gate electrode, and the auxiliary electrode is disposed on a surface of the active layer near or away from the gate electrode.

According to an embodiment of the present application, material of the active layer is oxide semiconductor or silicon semiconductor.

Advantages of the embodiment of the present application are as follows: The embodiment of the present application provides a display panel, the display panel comprises an electrostatic protection circuit, the electrostatic protection circuit comprises at least one thin film transistor, and the thin film transistor comprises an active layer. The active layer has a channel portion. Disposing at least one auxiliary electrode on the channel portion and making the auxiliary electrode contact the channel portion can use the additional auxiliary electrode to increase uniformity of plasma applied to the channel portion to lower a leakage current of the thin film transistor such that display quality of the display panel can be improved.

### DESCRIPTION OF DRAWINGS

FIG. 1 is a partial schematic view of a display panel of a first embodiment provided by an embodiment of the present application;

FIG. 2 is a cross-sectional view of the display panel of the first embodiment as shown in FIG. 1 along a line A-A′ direction;

FIG. 3 is a partial schematic view of a display panel of a second embodiment provided by the embodiment of the present application;

FIG. 4 is a partial schematic view of a display panel of a third embodiment provided by the embodiment of the present application;

FIG. 5 is a partial schematic view of a display panel of a fourth embodiment provided by the embodiment of the present application;

FIG. 6 is a partial schematic view of a display panel of a fifth embodiment provided by the embodiment of the present application;

FIG. 7 is a cross-sectional view of a display panel of a sixth embodiment of the embodiment of the present application along the line A-A′ direction.

### DETAILED DESCRIPTION OF PREFERRED EMBODIMENTS

Each of the following embodiments is described with appending figures to illustrate specific embodiments of the present invention that are applicable. The terminologies of direction mentioned in the present invention, such as “upper”, “lower”, “front”, “rear”, “left”, “right”, “inner”, “outer”, “side surface”, etc., only refer to the directions of the appended figures. Therefore, the terminologies of direction are used for explanation and comprehension of the present invention, instead of limiting the present invention. In the figures, units with similar structures are marked with the same reference characters.

Descriptions will be made with attached drawings and specific embodiments to the present application as follows.

The embodiment of the present application provides a display panel that can reduce a leakage current of a thin film transistor in an electrostatic protection circuit to improve display quality of the display panel.

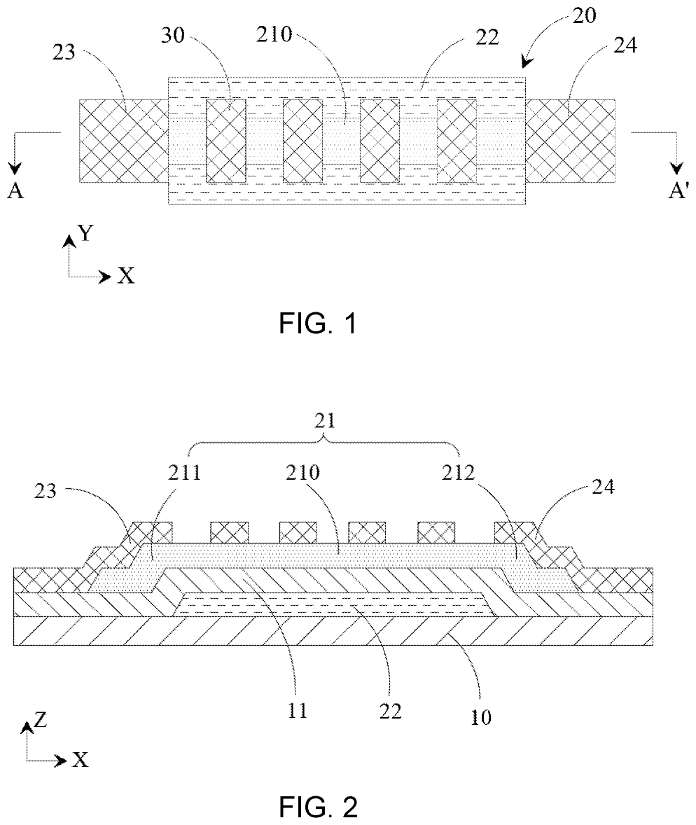

With reference to FIGS. 1 and 2, the display panel comprises a substrate 10 and an electrostatic protection circuit disposed on the substrate 10. In the embodiment of the present application, the display panel is a liquid crystal display panel, and the substrate 10 is a glass substrate.

In particular, the display panel can be a fringe field switching (FFS) mode liquid crystal display panel. The display panel can comprises a display region and a non-display region surrounding the display region. The electrostatic protection circuit can be disposed on four corners of the non-display region surrounding the display region and a top end of the non-display region.

Furthermore, the electrostatic protection circuit comprises at least one thin film transistor 20. The thin film transistor 20 comprises an active layer 21. The active layer 21 comprises a source electrode contact portion 211, a drain electrode contact portion 212, and a channel portion 210. The channel portion 210 is disposed between the source electrode contact portion 211 and the drain electrode contact portion 212.

The thin film transistor 20 further comprises a gate electrode 22, a source electrode 23, and a drain electrode 24. The gate electrode 22 is disposed on the substrate 10. The source electrode 23 and the drain electrode 24 are disposed on a side of the active layer 21 away from the gate electrode 22. The source electrode 23 contacts the source electrode contact portion 211 of the active layer 21. The drain electrode 24 contacts the drain electrode contact portion 212 of the active layer 21.

It should be explained that the gate electrode 22 disposed on the substrate 10 can be the gate electrode 22 located above the substrate 10 and directly contacting the substrate 10, or can be the gate electrode 22 located above the substrate 10 but disposed at an interval from the substrate 10 with an intervening layer (for example, an insulation layer, a buffer layer, etc.

In the embodiment as shown in FIG. 2, the gate electrode 22 is disposed above the substrate 10 and directly contacts the substrate 10. A gate electrode insulation layer 11 is disposed above the gate electrode 22. The active layer 21 is disposed on a surface of the gate electrode insulation layer 11 away from the gate electrode 22. The source electrode 23 and the drain electrode 24 are disposed on a surface of the active layer 21 away from the gate electrode insulation layer 11.

Furthermore, at least one auxiliary electrode 30 is disposed on the channel portion 210, and the auxiliary electrode 30 directly contacts the channel portion 210.

In one of the embodiments, the auxiliary electrode 30 is plural and the auxiliary electrodes 30 are disposed on the channel portion 210. The auxiliary electrodes 30 are disposed at intervals along a channel length direction.

It should be explained that in the embodiment of the present application, the channel length direction is a first direction X as shown in FIG. 1, and a channel width direction is a second direction Y as shown in FIG. 1. A thickness direction of the display panel is a third direction Z as shown in FIG. 2. In the embodiment of the present application, the first direction X is perpendicular to the second direction Y, and the third direction Z is perpendicular to the first direction X and the second direction Y. In actual applications, the first direction X and the second direction Y can also intersect each other but be not perpendicular to each other, and no limit is here.

With reference to FIG. 1, in a plane defined by the first direction X and the second direction Y, the channel portion 210 is a straight-line strip, four auxiliary electrodes 30 are disposed on the channel portion 210, the four auxiliary electrodes 30 are disposed at intervals on the channel portion 210 along the first direction X. The four auxiliary electrodes 30 do not connected to one another, the auxiliary electrodes 30 contact the channel portion 21 but are not connected to other signal wiring.

In one of the embodiments, the auxiliary electrodes 30 can be distributed on the channel portion 210 along the first direction X at equal intervals.

In one of the embodiments, in the second direction Y, a length of the auxiliary electrode 30 is greater than a length of the channel portion 210 such that a contact area between the auxiliary electrode 30 and the channel portion 210 can be increased and resistance between the auxiliary electrode 30 and the channel portion 210 can be decreased to guarantee that the auxiliary electrode 30 can conductively connect the adjacent short channels. In some other embodiments, in the second direction Y, the length of the auxiliary electrode 30 can also be equal to the length of the channel portion 210.

With reference to 2, four auxiliary electrodes 30 are located on a surface of the channel portion 210 away from the substrate 10 and directly contact the channel portion 210. A notch is defined between adjacent two of the auxiliary electrode 30, and the notch exposes a part of the channel portion 210.

In the present embodiment, the auxiliary electrode 30, the source electrode 23, and the drain electrode 24 are disposed in the same layer. The auxiliary electrode 30 can be formed with the source electrode 23 and the drain electrode 24 by the same metal formation process.

In the present embodiment, material of the active layer is an oxide semiconductor. In particular, material of the active layer is indium gallium zinc oxide (IGZO). In some other embodiments, material of the active layer can also be a silicon semiconductor, for example, amorphous silicon or polysilicon.

For example as shown in FIG. 2, it is assumed that no auxiliary electrode 30 is disposed above the channel portion 210, after the source electrode 23 and the drain electrode 24 formed on the active layer 21, it is also required to form an insulation layer of silicon oxide material on the active layer 21, the source electrode 23, and the drain electrode 24 by a process of chemical vapor deposition. Because a length of the channel portion 210 is longer, during the chemical vapor deposition process, plasma cannot be evenly applied to each region of the channel portion 210 and results in uneven oxygenation to the channel portion 210 such that the thin film transistor easily generates a greater leakage current to effect an display effect of the display panel.

The present embodiment disposes four auxiliary electrodes 30 above the channel portion 210. The four auxiliary electrodes 30 shield a part of the surface of the channel portion 210 and divide the channel portion 210 with a longer length into five short channels with shorter lengths. Adjacent two of the short channels can be electrically connected to each other by the auxiliary electrode 30. In a subsequent chemical vapor deposition process, plasma can be more evenly applied to the five short channels with the shorter lengths such that oxygenation to the short channel is more even. As such, a leakage current of the thin film transistor can be reduced to improve a display effect of the display panel and to raise a protection effect of the electrostatic protection circuit.

In actual applications, a number of the auxiliary electrodes 30 disposed above the channel portion 210 can be configured the channel length of the channel portion 210 according to and is not limited in four of the above embodiment. Also, one, two, three, and more of the auxiliary electrodes 30 can be disposed on the channel portion 210.

In one of the embodiments, the channel portion 210 is at least partially bending.

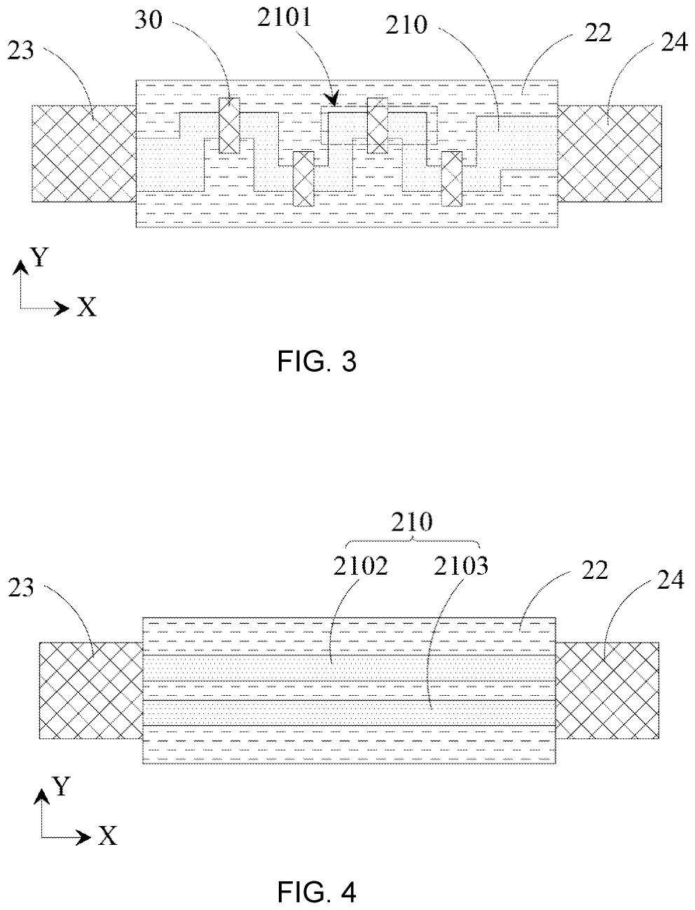

With reference to FIG. 3, a structure of the display panel of the second embodiment as shown in FIG. 3 is substantially the same as the structure of the display panel of the first embodiment as shown in FIG. 1, and a difference is that: the channel portion 210 in the display panel of the second embodiment as shown in FIG. 3 comprises a plurality of bending sections 2101, and bending directions of any adjacent two of the bending sections 2101 are different. One of adjacent two of the bending sections 2101 protrudes along the second direction Y, and the other protrudes along a direction opposite to the second direction Y. The bending sections 2101 are connected sequentially to form the wavy channel portion 210.

Compared to the embodiment as shown in FIG. 1, the embodiment as shown in FIG. 3 can make at least a part of the channel portion 210 bending without increasing a size of the thin film transistor. Bending of at least one part of the channel portion 210 can increase the channel length of the thin film transistor to improve a resistance of the thin film transistor to further reduce a leakage current of the thin film transistor to further improve the display effect of the display panel and raise the protection effect of the electrostatic protection circuit.

Furthermore, an auxiliary electrode 30 is disposed on each of the bending sections 2101.

With reference to FIG. 3, the channel portion 210 comprises four bending sections 2101 connected sequentially, and the auxiliary electrode 30 is disposed above a middle region of each of the bending sections 2101.

In one of the embodiments, the channel portion 210 comprises at least two sub-channel portions, and the sub-channel portions are disposed at intervals along the channel width direction.

With reference to FIG. 4, a structure of the display panel of the third embodiment as shown in FIG. 4 and the structure of the display panel of the first embodiment as shown in FIG. 1 are substantially the same, and a difference is that: the channel portion 210 in the display panel in the third embodiment as shown in FIG. 4 comprises two sub-channel portions that are a first sub-channel portions 2102 and a second sub-channel portions 2103, respectively. Both the first sub-channel portions 2102 and the second sub-channel portions 2103 are straight-line strips. The first sub-channel portions 2102 and the second sub-channel portions 2103 are disposed at an interval along the second direction Y and are parallel to the second sub-channel portions 2103.

A first end of the first sub-channel portions 2102 and a first end of the second sub-channel portions 2103 are connected to the same source electrode contact portion. A second end of the first sub-channel portions 2102 and a second end of the second sub-channel portions 2103 are connected to the same drain electrode contact portion.

Compared to the embodiment as shown in FIG. 1, the embodiment as shown in FIG. 4 divides the channel portion 210 into two sub-channel portions disposed at an interval along the channel width direction to reduce a channel width of the channel portion 210 such that a risk of device failure resulting from heat accumulation generated by the large voltage of large current of the static electricity can be decreased.

In one of the embodiments, in the second direction Y, widths of the first sub-channel portions 2102 and the second sub-channel portions 2103 are equal.

In actual applications, the channel portion 210 not only can be divide into two sub-channel portions of the above embodiment, but also can be divided into three sub-channel portions disposed at intervals, and it can also achieve the technical effect similar to that of the above embodiment, and no limit is here.

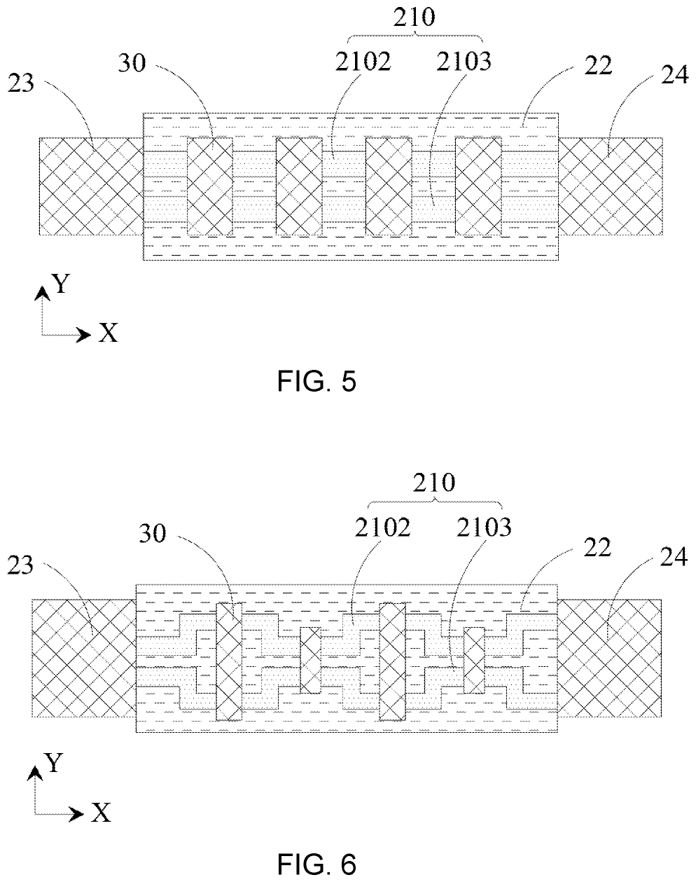

With reference to FIG. 5, the structure of the display panel of the fourth embodiment as shown in FIG. 5 and the structure of the display panel of the third embodiment as shown in FIG. 4 are substantially the same, and a difference is that: in the display panel of the fourth embodiment as shown in FIG. 5, the auxiliary electrode 30 crosses at least adjacent two of the sub-channel portions.

In the embodiment as shown in FIG. 5, a plurality of auxiliary electrodes 30 are disposed on the channel portion 210. The auxiliary electrodes 30 all cross the first sub-channel portions 2102 and the second sub-channel portions 2103 and electrically connect the first sub-channel portions 2102 and the second sub-channel portions 2103. Under such structure, not only the risk of failure of heated device due to a large voltage or large current can be decreased, but also uniformity of plasma applied to the channel portion 210 in a subsequent process can be improved such that a leakage current of the thin film transistor can be reduced to improve display effect of the display panel and raise a protection effect of the electrostatic protection circuit.

In some other embodiments, a plurality of auxiliary electrodes can be disposed in each of different sub-channel portions, and the auxiliary electrodes in the different sub-channel portions are disposed at intervals. For example, a plurality of auxiliary electrodes 30 can be disposed on each of the first sub-channel portion 2102 and the second sub-channel portion 2103, and the auxiliary electrodes 30 on the first sub-channel portions 2102 are not connected to the auxiliary electrodes 30 on the second sub-channel portions 2103.

In one of the embodiments, adjacent two of the sub-channel portions are disposed symmetrically.

With reference to FIG. 6, the structure of the display panel of the fifth embodiment as shown in FIG. 6 and the structure of the display panel of the fourth embodiment as shown in FIG. 5 are substantially the same, and a difference is that: the sub-channel portions of the display panel in the fourth embodiment as shown in FIG. 6 are straight-line strips, and the sub-channel portions of the display panel of the fifth embodiment as shown in FIG. 6 are at least partially bending.

In the embodiment as shown in FIG. 6, the channel portion 210 comprises the first sub-channel portions 2102 and the second sub-channel portions 2103. The first sub-channel portions 2102 and the second sub-channel portions 2103 are disposed at intervals along the second direction Y. Both the first sub-channel portion 2102 and the second sub-channel portion 2103 comprise a plurality of bending sections. A bending direction of any one of the bending sections on the first sub-channel portion 2102 is opposite to a bending direction of the corresponding bending sections on the second sub-channel portions 2103. The first sub-channel portions 2102 and the second sub-channel portions 2103 are disposed symmetrically.

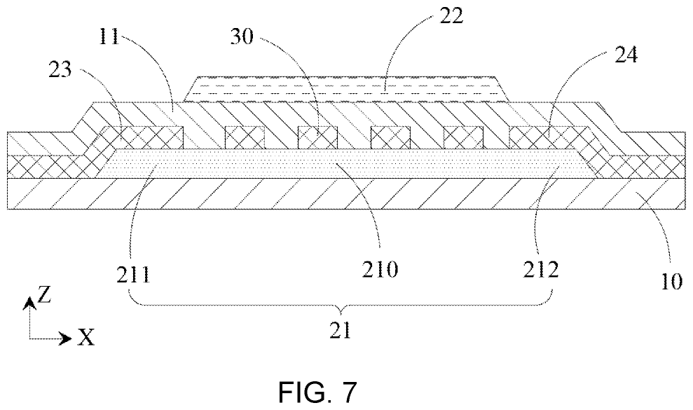

With reference to 7, the structure of the display panel of the sixth embodiment as shown in FIG. 7 and the structure of the display panel of the first embodiment in FIGS. 1 and 2 are substantially the same, and a difference is that: the display panel of the first embodiment as shown in FIGS. 1 and 2 is a bottom gate structure, the display panel as shown in FIG. 7 is a top gate structure, and the auxiliary electrode 30 is disposed on a surface of the active layer 21 near the gate electrode 22.

In particular, in the embodiment as shown in FIG. 7, the active layer 21 is located on the substrate 10 and directly contacts the substrate 10. The source electrode 23, drain electrode 24 and the auxiliary electrode 30 are disposed on a surface of the active layer 21 away from the substrate 10. The gate electrode insulation layer 11 is disposed on surfaces of the source electrode 23, the drain electrode 24, and the auxiliary electrode 30 away from the substrate 10. The gate electrode 22 is disposed on a a surface of the gate electrode insulation layer 11 away from the substrate 10.

It should be explained that the electrostatic protection circuit in the embodiment of the present application can have one or a plurality of thin film transistors. When the electrostatic protection circuit has a plurality of thin film transistors, a structure of the thin film transistor can be the same as a structure of the thin film transistor 20 of the embodiment of the present application. A circuit structure of the electrostatic protection circuit in the embodiment of the present application can refer to a circuit structure of a conventional electrostatic protection circuit, and no limit is here.

Advantages of the embodiment of the present application are as follows: The embodiment of the present application provides a display panel, the display panel comprises an electrostatic protection circuit, the electrostatic protection circuit comprises at least one thin film transistor, and the thin film transistor comprises an active layer. The active layer has a channel portion. Disposing at least one auxiliary electrode on the channel portion and making the auxiliary electrode contact the channel portion can use the additional auxiliary electrode to increase uniformity of plasma applied to the channel portion to lower a leakage current of the thin film transistor such that display quality of the display panel can be improved.

Although the preferred embodiments of the present invention have been disclosed as above, the aforementioned preferred embodiments are not used to limit the present invention. The person of ordinary skill in the art may make various changes and modifications without departing from the spirit and scope of the present invention. Therefore, the scope of protection of the present invention is defined by the scope of the claims.

What is claimed is:

1. A display panel, comprising an electrostatic protection circuit, wherein the electrostatic protection circuit comprises a thin film transistor that comprises an active layer comprising:
a channel portion; and
at least one auxiliary electrode contacting the channel portion directly.

2. The display panel according to claim 1, wherein at least one auxiliary electrode is plural, the auxiliary electrodes are disposed on the channel portion, and the auxiliary electrodes are distributed at intervals along a channel length direction.

3. The display panel according to claim 1, wherein the channel portion is at least partially bending.

4. The display panel according to claim 3, wherein the channel portion comprises a plurality of bending sections, and bending directions of adjacent two of the bending sections are different.

5. The display panel according to claim 4, wherein each of the at least one auxiliary electrode is disposed on each of the bending sections.

6. The display panel according to claim 1, wherein the channel portion comprises at least two sub-channel portions, and the sub-channel portions are disposed at intervals along a channel width direction.

7. The display panel according to claim 1, wherein adjacent two of the sub-channel portions are parallel to each other or disposed symmetrically.

8. The display panel according to claim 1, wherein the thin film transistor further comprises a source electrode and a drain electrode, and the auxiliary electrode, the source electrode, and the drain electrode are disposed in a same layer.

9. The display panel according to claim 1, wherein the thin film transistor comprises a gate electrode, and the auxiliary electrode is disposed on a surface of the active layer near or away from the gate electrode.

10. The display panel according to claim 1, wherein material of the active layer is oxide semiconductor or silicon semiconductor.

11. A display panel, comprising an electrostatic protection circuit, wherein the electrostatic protection circuit comprises a thin film transistor that comprises an active layer comprising:
a channel portion; and
at least one auxiliary electrode contacting the channel portion directly;
wherein at least one auxiliary electrode is plural, the auxiliary electrodes are disposed on the channel portion, and the auxiliary electrodes are distributed at intervals along a channel length direction;
wherein the channel portion is at least partially bending.

12. The display panel according to claim 11, wherein the channel portion comprises a plurality of bending sections, and bending directions of adjacent two of the bending sections are different.

13. The display panel according to claim 12, wherein each of the auxiliary electrodes is disposed on each of the bending sections.

14. The display panel according to claim 11, wherein the channel portion comprises at least two sub-channel portions, and the sub-channel portions are disposed at intervals along a channel width direction.

15. The display panel according to claim 11, wherein adjacent two of the sub-channel portions are parallel to each other or disposed symmetrically.

16. The display panel according to claim 11, wherein the thin film transistor further comprises a source electrode and a drain electrode, and the auxiliary electrode, the source electrode, and the drain electrode are disposed in a same layer.

17. The display panel according to claim 11, wherein the thin film transistor comprises a gate electrode, and the auxiliary electrode is disposed on a surface of the active layer near or away from the gate electrode.

18. The display panel according to claim 11, wherein material of the active layer is oxide semiconductor or silicon semiconductor.
